(19) United States
(12) Patent Application Publication
(10) Pub. No.: US 2026/0299031 A1
(43) Pub. Date: Oct. 1, 2026

(54) APPARATUS FOR DIAGNOSING BATTERY AND METHOD THEREOF

(71) Applicants: Hyundai Motor Company, Seoul (KR); Kia Corporation, Seoul (KR); UIF (University Industry Foundation), Yonsei University, Seoul (KR)

(72) Inventors: Jae Kyung OH, Hwaseong-Si (KR); Seong Yoon KIM, Incheon (KR); Min Ho LEE, Seoul (KR); Jung Il CHOI, Goyang-si (KR); Kyung Hyun KIM, Seoul (KR)

(21) Appl. No.: 19/360,294

(22) Filed: Oct. 16, 2025

(30) Foreign Application Priority Data
Mar. 28, 2025 (KR) 10-2025-0040085

(51) Int. Cl. G01R 31/367; B60L 58/16; G01R 31/371; G01R 31/3842; G01R 31/389; G01R 31/392

(52) U.S. Cl. CPC G01R 31/367; B60L 58/16; G01R 31/371; G01R 31/3842; G01R 31/389; G01R 31/392

(57) ABSTRACT

Disclosed are a battery diagnosing apparatus and a method thereof. The battery diagnosing apparatus identifies at least one key data associated with a signal characteristic of a battery or an electrochemical characteristic of the battery from data associated with the battery, identifies first key data, which is used to set a criterion associated with failure of the battery, from among the at least one key data, updates a multiclass algorithm for performing a diagnosis associated with the failure of the battery based on the first key data, and performs the diagnosis associated with the failure of the battery based on at least one of at least one key data, or the multiclass algorithm, or any combination thereof.

### CROSS-REFERENCE TO RELATED APPLICATION

This application claims the benefit of priority to Korean Patent Application No. 10-2025-0040085, filed in the Korean Intellectual Property Office on Mar. 28, 2025, the entire contents of which are incorporated herein by reference.

### TECHNICAL FIELD

The present disclosure relates to a battery diagnosing apparatus and a method thereof, and more particularly, relates to a technology for diagnosing the condition of a battery by using a multiclass algorithm.

### BACKGROUND

The use of lithium-ion (Li-ion) batteries is growing rapidly in a variety of applications, including electric vehicles (EVs). Li-ion batteries may provide high energy density and power density. As such, Li-ion batteries may store a lot of energy in a limited space and may output the energy quickly. Moreover, due to their long life and environmental benefits, the Li-ion batteries are widely used as ideal energy storage devices in a variety of applications such as portable electronic devices, energy storage systems, and electric vehicles.

However, internal and/or external defects may occur in Li-ion batteries during operation, which may cause serious safety issues such as degraded performance, thermal runaway, fire, and explosion. Accordingly, it is very important to maintain the safety and reliability of a system by early diagnosing whether a battery fails. To this end, a battery management system (BMS), for example, may include a fault diagnosis function, thereby ensuring safe and reliable operation of the battery by detecting a fault early and taking appropriate control measures.

A data-driven method and/or a circuit model-based method may be used to diagnose a battery failure.

The data-driven method refers to a method of detecting abnormal patterns by analyzing operational data of an actual battery. The data-driven method may be useful for detecting signs of battery failure. The circuit model-based method refers to a method of predicting the condition of a battery by modeling the electrical characteristics of the battery. The circuit model-based method may be used to predict changes in the performance of the battery.

These fault diagnosis methods may be limited in that they may be primarily developed in idealized environments, such as laboratories, and thus may not fully reflect various conditions and the complexity of real operating environments.

For example, the data-driven method may not be robust to observation errors and/or data incompleteness. The data-driven method may be difficult to apply in real-time/near real-time. The circuit model-based method may not fully reflect complex electrochemical fault mechanisms inside the battery, which may limit the accuracy and speed of fault diagnosis. The circuit model-based method may be difficult to apply in real-time (e.g., to a BMS) due to its high computational costs.

The matters described in this Background section are only for enhancement of understanding of the background of the disclosure, and should not be taken as acknowledgement that they correspond to prior art already known to those skilled in the art.

### SUMMARY

The following summary presents a simplified summary of certain features. The summary is not an extensive overview and is not intended to identify key or critical elements.

Systems, apparatuses/devices, and methods are described for diagnosing/managing a battery. A battery management apparatus may comprise: a memory configured to store one or more instructions; and a processor configured to execute the one or more instructions, wherein the processor, by executing the one or more instructions, is configured to cause the battery management apparatus to: receive, from one or more sensors, data associated with a physical state of the battery; identify, based on the data, at least one key data associated with: a signal characteristic of the battery, or an electrochemical characteristic of the battery; identify first key data, from among the at least one key data, for setting a criterion associated with failure of the battery; update, based on the first key data, a multiclass algorithm for performing a diagnosis associated with a failure state of the battery; diagnose, based on at least one of the at least one key data or the multiclass algorithm, the failure state of the battery; and control, based on the diagnosed failure state of the battery, usage of the battery. A vehicle may comprise a battery and the battery management apparatus.

A method may be performed by an apparatus of a vehicle (e.g., the battery management apparatus associated with a battery of the vehicle). The method may comprise: receiving, from one or more sensors, data associated with a physical state of a battery of the vehicle; identifying, by a processor circuit and based on the data, at least one key data associated with: a signal characteristic of the battery, or an electrochemical characteristic of the battery; identifying, by the processor circuit and from among the at least one key data, first key data for setting a criterion associated with failure of the battery; updating, by the processor circuit and based on the first key data, a multiclass algorithm for performing a diagnosis associated with a failure state of the battery; diagnosing, by the processor circuit and based on at least one of the at least one key data or the multiclass algorithm, the failure state of the battery; and controlling, by the processor circuit and based on the diagnosed failure state of the battery, usage of the battery.

These and other features and advantages are described in greater detail below.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram showing a battery diagnosing apparatus, according to an example of the present disclosure;

FIG. 2 is a drawing showing an example of a process in which a battery diagnosing apparatus determines whether a battery is faulty, according to an example of the present disclosure;

FIG. 3 is a drawing showing an example of a pulse-based analysis technique associated with a battery diagnosing apparatus, according to an example of the present disclosure;

FIG. 4 is a drawing for describing an example of signal characteristics of a battery associated with a battery diagnosing apparatus, according to an example of the present disclosure;

FIG. 5 is a drawing for describing an example of electrochemical characteristics of a battery associated with a battery diagnosing apparatus, according to an example of the present disclosure;

FIG. 6 is a diagram showing an example of a process, in which a battery diagnosing apparatus determines whether a battery is faulty by using a multiclass algorithm, according to an example of the present disclosure;

FIG. 7A is a diagram illustrating an example, in which a battery diagnosing apparatus updates a multiclass algorithm by using first key data, according to an example of the present disclosure;

FIG. 7B is a graph showing the distribution of key data that a battery diagnosing apparatus according to an example of the present disclosure identifies to determine whether there is potential failure;

FIG. 8 is a drawing showing an example of a specific process, in which a battery diagnosing apparatus determines whether a battery is faulty by using a symbolic equation and a multiclass algorithm, according to an example of the present disclosure;

FIG. 9 is a flowchart for describing a battery diagnosing apparatus or a battery diagnosing method, according to an example of the present disclosure; and

FIG. 10 is a diagram showing a computing system associated with a battery diagnosing apparatus or a battery diagnosing method, according to an example of the present disclosure.

### DETAILED DESCRIPTION

Hereinafter, some examples of the present disclosure will be described in detail with reference to the accompanying drawings. In adding reference numerals to components of each drawing, it should be noted that the same components include the same reference numerals, although they are indicated on another drawing. Furthermore, in describing the examples of the present disclosure, detailed descriptions associated with well-known functions or configurations will be omitted if they may make subject matters of the present disclosure unnecessarily obscure.

In describing elements of an example of the present disclosure, the terms first, second, A, B, (a), (b), and the like may be used herein. These terms are only used to distinguish one element from another element, but do not limit the corresponding elements irrespective of the nature, order, or priority of the corresponding elements. Moreover, the expression “at least one of A, B, or C or any combination thereof” may include “A, B, or C, or any combination thereof such as AB, BC, AC, or ABC”. The phrase “one or more of” is used interchangeably with “at least one of” herein.

Furthermore, unless otherwise defined, all terms used herein, including technical or scientific terms, include the same meaning as commonly understood by one of ordinary skill in the technical field to which the present disclosure belongs. It will be understood that terms used herein should be interpreted as including a meaning that is consistent with their meaning in the context of the present disclosure and the relevant art and will not be interpreted in an idealized or overly formal sense unless expressly so defined herein.

The expressions such as “comprise,” “may comprise,” “include,” “may include,” “have,” “may have,” etc. as used herein are intended to mean the presence of a characteristic (e.g., function, operation, component, etc.) and do not exclude the presence of other additional characteristics. That is, these expressions should be understood as open-ended terms that encompass the possibility that other examples are included.

A singular expression used herein may include the meaning of the plural unless otherwise stated in the context, which also applies to the singular expression described in the claims.

Expressions such as “first” or “second” as used herein are used to distinguish one object from another in referring to multiple similar objects, unless otherwise indicated in context, and do not limit the order or importance between them. For example, a plurality of chips according to the present disclosure may be distinguished from each other by referring them as “first chip,” “second chip,” respectively.

The term “unit” as used herein may refer to software, or hardware component such as Field-Programmable Gate Array (FPGA), Application Specific Integrated Circuit (ASIC), etc. However, “unit” is not limited to hardware and software. The “unit” may be configured to be stored in an addressable storage medium, or may be configured to execute one or more processors. The “unit” may include components such as software components, object-oriented software components, class components, and task components, as well as processors, functions, attributes, procedures, subroutines, segments of program code, drivers, firmware, microcode, circuits, data, databases, data structures, tables, arrays, and variables.

The expression “based” on as used herein is intended to describe one or more factors that influence an act or operation of determining or deciding described in a phrase or sentence including that expression, and this expression does not exclude any additional factors that influence the act or operation of determining or deciding.

When it is described that a component (e.g., a first component) is “connected” or “coupled” to another component (e.g., a second component) as used herein, it may mean that the component is not only directly connected or coupled to another component, but also connected or coupled through yet another component (e.g., a third component).

Depending on the context, the expression “configured to” as used herein may have meanings such as “set to,” “with the ability to,” “modified to,” “made to,” “to be able to,” etc. This expression is not limited to the meaning of “specially designed in hardware to.” For example, a processor configured to perform a specific operation may refer to a generic purpose processor capable of performing the specific operation by executing software, or to a special purpose computer structured through programming to perform the specific operation.

Methods and/or algorithms for identifying electrochemical factors associated with failure in a dynamic profile (e.g., of a battery and/or battery system) may help overcome difficulties in effectively diagnose faults in the battery.

An automation level of an autonomous driving vehicle may be classified as follows, according to the American Society of Automotive Engineers (SAE). At autonomous driving level 0, the SAE classification standard may correspond to “no automation,” in which an autonomous driving system is temporarily involved in emergency situations (e.g., automatic emergency braking) and/or provides warnings only (e.g., blind spot warning, lane departure warning, etc.), and a driver is expected to operate the vehicle. At autonomous driving level 1, the SAE classification standard may correspond to “driver assistance,” in which the system performs some driving functions (e.g., steering, acceleration, brake, lane centering, adaptive cruise control, etc.) while the driver operates the vehicle in a normal operation section, and the driver is expected to determine an operation state and/or timing of the system, perform other driving functions, and cope with (e.g., resolve) emergency situations. At autonomous driving level 2, the SAE classification standard may correspond to “partial automation,” in which the system performs steering, acceleration, and/or braking under the supervision of the driver, and the driver is expected to determine an operation state and/or timing of the system, perform other driving functions, and cope with (e.g., resolve) emergency situations. At autonomous driving level 3, the SAE classification standard may correspond to “conditional automation,” in which the system drives the vehicle (e.g., performs driving functions such as steering, acceleration, and/or braking) under limited conditions but transfer driving control to the driver when the required conditions are not met, and the driver is expected to determine an operation state and/or timing of the system, and take over control in emergency situations but do not otherwise operate the vehicle (e.g., steer, accelerate, and/or brake). At autonomous driving level 4, the SAE classification standard may correspond to “high automation,” in which the system performs all driving functions, and the driver is expected to take control of the vehicle only in emergency situations. At autonomous driving level 5, the SAE classification standard may correspond to “full automation,” in which the system performs full driving functions without any aid from the driver including in emergency situations, and the driver is not expected to perform any driving functions other than determining the operating state of the system. Although the present disclosure may apply the SAE classification standard for autonomous driving classification, other classification methods and/or algorithms may be used in one or more configurations described herein.

One or more features associated with autonomous driving control may be activated based on configured autonomous driving control setting(s) (e.g., based on at least one of: an autonomous driving classification, a selection of an autonomous driving level for a vehicle, etc.). Based on one or more features (e.g., feature of a diagnosed failure state of a battery) described herein, an operation of the vehicle may be controlled. The vehicle control may include various operational controls associated with the vehicle (e.g., autonomous driving control, sensor control, braking control, braking time control, acceleration control, acceleration change rate control, alarm timing control, forward collision warning time control, etc.).

One or more auxiliary devices (e.g., engine brake, exhaust brake, hydraulic retarder, electric retarder, regenerative brake, etc.) may also be controlled, for example, based on one or more features (e.g., feature of a diagnosed failure state of a battery) described herein.

One or more communication devices (e.g., a modem, a network adapter, a radio transceiver, an antenna, etc., that is capable of communicating via one or more wired or wireless communication protocols, such as Ethernet, Wi-Fi, near-field communication (NFC), Bluetooth, Long-Term Evolution (LTE), 5G New Radio (NR), vehicle-to-everything (V2X), etc.) may also be controlled, for example, based on one or more features (e.g., feature of a diagnosed failure state of a battery) described herein.

Minimum risk maneuver (MRM) operation(s) may also be controlled, for example, based on one or more features (e.g., feature of a diagnosed failure state of a battery) described herein. A minimal risk maneuvering operation (e.g., a minimal risk maneuver, a minimum risk maneuver) may be a maneuvering operation of a vehicle to minimize (e.g., reduce) a risk of collision with surrounding vehicles in order to reach a lowered (e.g., minimum) risk state. A minimal risk maneuver may be an operation that may be activated during autonomous driving of the vehicle when a driver is unable to respond to a request to intervene. During the minimal risk maneuver, one or more processors of the vehicle may control a driving operation of the vehicle for a set period of time.

Biased driving operation(s) may also be controlled, for example, based on one or more features (e.g., feature of a diagnosed failure state of a battery) described herein. A driving control apparatus may perform a biased driving control. To perform a biased driving, the driving control apparatus may control the vehicle to drive in a lane by maintaining a lateral distance between the position of the center of the vehicle and the center of the lane. For example, the driving control apparatus may control the vehicle to stay in the lane but not in the center of the lane. The driving control apparatus may identify or determine a biased target lateral distance for biased driving control. For example, a biased target lateral distance may comprise an intentionally adjusted lateral distance that a vehicle may aim to maintain from a reference point, such as the center of a lane or another vehicle, during maneuvers such as lane changes. This adjustment may be made to improve the vehicle's stability, safety, and/or performance under varying driving conditions, etc. For example, during a lane change, the driving control system may bias the lateral distance to keep a safer gap from adjacent vehicles, considering factors such as the vehicle's speed, road conditions, and/or the presence of obstacles, etc.

One or more sensors (e.g., IMU sensors, camera, LIDAR, RADAR, blind spot monitoring sensor, line departure warning sensor, parking sensor, light sensor, rain sensor, traction control sensor, anti-lock braking system sensor, tire pressure monitoring sensor, seatbelt sensor, airbag sensor, fuel sensor, emission sensor, throttle position sensor, inverter, converter, motor controller, power distribution unit, high-voltage wiring and connectors, auxiliary power modules, charging interface, etc.) may also be controlled, for example, based on one or more features (e.g., feature of a diagnosed failure state of a battery) described herein. An operation control for autonomous driving of the vehicle may include various driving control of the vehicle by the vehicle control device (e.g., acceleration, deceleration, steering control, gear shifting control, braking system control, traction control, stability control, cruise control, lane keeping assist control, collision avoidance system control, emergency brake assistance control, traffic sign recognition control, adaptive headlight control, etc.).

An autonomous driving activation/deactivation operation may be controlled based on one or more features (e.g., feature of a diagnosed failure state of a battery) described herein. In particular, a diagnostic control apparatus may determine a tracking status for objects around the vehicle from sensor data (e.g., LiDAR point clouds, radar returns, or camera detections) and gate autonomous driving accordingly. When the tracking status is normal (e.g., all detected objects are stably tracked within confidence thresholds despite environmental noise), autonomous driving may be enabled. When the tracking status is cautionary (e.g., one or more objects are intermittently lost, duplicated, or merged due to noise such as exhaust plumes, reflective road signs, or occlusion, etc.), autonomous driving may be restricted (e.g., speed/acceleration limits, route constraints, or reduced feature set), and a driver takeover request may be prepared. When the tracking status is critical (e.g., an object track is lost, falsely maintained, or corrupted by severe noise or occlusion), autonomous driving may be deactivated and a minimal risk maneuver initiated (e.g., controlled deceleration, lane-keeping to shoulder, or safe stop), while issuing a warning that includes tracking channel and object identification information.

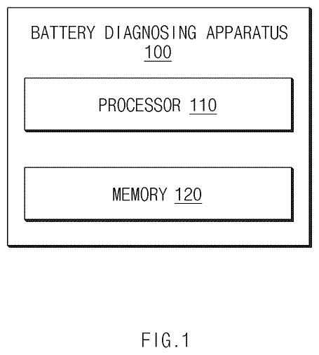

Hereinafter, examples of the present disclosure will be described in detail with reference to FIGS. 1 to 10.

FIG. 1 is a block diagram showing a battery diagnosing apparatus, according to an example of the present disclosure.

Referring to FIG. 1, a battery diagnosing apparatus 100 (e.g., alternatively referred to as a battery management apparatus) according to an example of the present disclosure may be implemented inside and/or on or otherwise in communication with a vehicle. In this case, the battery diagnosing apparatus 100 may be integrated with one or more control units (e.g., control circuitry, controllers) of a vehicle and/or may be implemented as a separate device configured to be coupled with the one or more control units of the vehicle by a separate connection device and/or communication means.

As another example, the battery diagnosing apparatus 100 according to an example of the present disclosure may be implemented in a device for diagnosing a battery. For example, the battery diagnosing apparatus 100 may be implemented in a terminal (e.g., computing device/interface of a vehicle) for diagnosing a battery. The terminal may comprise a user interface, which may be a device through which a human user can interact with a device. The user interface may include an input interface (also referred to as an input device) that can receive an input from the human user and/or an output interface (also referred to as an output device) through which data or information can be output to the human user. An input interface may include, for example, a button, a knob, a toggle, a switch, a dial, a slider, a keyboard, a touchscreen, a control panel, an instrumentation panel, a center console (also referred to as a central console), a microphone, a stalk (e.g., a control stalk), a gear shift control (e.g., a gear stick, a gear stalk, etc.), a camera, a wheel, a steering wheel, a pedal, a lever, etc. An output interface may include, for example, a light (e.g., an indicator light), a lamp, an indicator, a screen, a display, a console, a dashboard, a meter, a gauge, a speaker, etc. Any of the input interfaces described herein may also be an output interface, and vice versa. For example, a center console may be considered both an input interface (e.g., equipped with buttons, knobs, sliders, a touchscreen, etc.) and an output interface (e.g., equipped with a display, indicator lights, etc.).

According to an example, the battery diagnosing apparatus 100 may include a processor 110 and a memory 120. The configuration of the battery diagnosing apparatus 100 shown in FIG. 1 is an example, and the present disclosure is not limited thereto. For example, the battery diagnosing apparatus 100 may further include multiple processors 110 and/or memories 120 (e.g., a distributed system) and/or components not illustrated in FIG. 1.

The processor 110 may be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like. For example, the “processor” may refer to a combination of processing devices such as a combination of a DSP and a microprocessor, a combination of a plurality of microprocessors, a combination of one or more microprocessors combined with a DSP core, or any other such combination. The processor 110 may read information from a memory 120 and/or record the information in the memory 120, as the memory 120 may be in a state of electronic communication with a processor. Memory 120 integrated into the processor 110 is in a state of electronic communication with the processor 110.

The processor 110 (e.g., processor circuit/processor circuitry) may function, in part, as a controller (control circuit/control circuitry). A controller (e.g., control circuit/control circuitry) may include a communication device communicating with other controllers or a sensor to control one or more functions and/or operations in charge, a memory storing an operation system, a logic command, and input/output information, and/or one or more processors performing determination, calculation, and decision necessary for controlling the function in charge. A controller may include, for example, a processor, a central processing unit (CPU), a microchip, a logic, an application-specific integrated circuit (ASIC), memory, etc. A controller may manipulate and/or control other components in the system (e.g., vehicle).

According to an example, the memory 120 may store instructions or data. For example, the memory 120 may store one or more instructions that, if executed by the processor 110, cause the battery diagnosing apparatus 100 to perform various operations. For example, the one or more instructions may be provided as a computer program stored in a computer-readable recording medium in order to be executed on a computer (e.g., the processor 110 of the battery diagnosing apparatus 100). The medium may either continuously store a computer-executable program or temporarily store the program for execution or download. Furthermore, the medium may be a variety of recording or storage means in the form of a single hardware device or multiple combined hardware devices, and is not limited to media directly connected to some computer system but may also be distributed across a network. Examples of such media include magnetic media such as a hard disk, a floppy disk, or a magnetic tape, optical recording media such as a compact disc ROM (CD-ROM) or a digital video disc (DVD), magneto-optical media such as a floptical disk, and a ROM, RAM, or flash memory, among others, configured to store program instructions. Additional examples of such media include media or storage media that are managed by an app store that distributes applications or by various other sites or servers that provide or distribute software.

According to an example, the memory 120 may be implemented as a single chipset with the processor 110 and may store various pieces of information associated with the battery diagnosing apparatus 100. For example, the memory 120 may store information about the operating history of the processor 110.

According to an example, the memory 120 may include a non-volatile memory (a read only memory (ROM)) and a volatile memory (a random access memory (RAM)). For example, data associated with the battery may be stored in the memory 120.

According to an example, the processor 110 may identify (e.g., receive, such as from a sensor configured to measure the data, measure, determine) data associated with the battery. Identifying the data associated with the battery may comprise, for example, receiving the data from one or more sensors configured to measure one or more physical properties of the battery/battery environment/battery output/input, etc. Identifying the data may comprise measuring/determining the data based on measurements by the one or more sensors, which may be part of and/or in communication with the battery diagnosing apparatus 100.

According to an example, the processor 110 may identify the data associated with the battery via a sensor (e.g., of or in communication with the battery diagnosing apparatus 100). For example, the processor 110 may identify/receive/measure, via the one or more sensors (such as a voltage sensor, a current sensor, a temperature sensor, or the like), data associated with the battery (such as a voltage, current, temperature of the battery, etc.).

In another example, the processor 110 may obtain the data associated with the battery from a server and/or another device (e.g., via wired and/or wireless communications). For example, the battery diagnosing apparatus 100 may receive the data associated with the battery from another device that identifies/receives the data associated with the battery.

The data associated with the battery may include various pieces of data about a state/operation of the battery. For example, data about a battery may include at least one of a voltage, a current, a temperature, an internal resistance, a power, a state of charge (SOC) of the battery, a state of health (SOH) of the battery, a state of power (SOP) of the battery, a cycle in which the battery repeats charging and discharging, a state of an electrolyte, a charging speed, a discharging speed, a capacity of the battery, and/or any combination thereof.

According to an example, the processor 110 may identify (e.g., select, determine), from/in the data associated with the battery, at least one key datum associated with a signal characteristic of the battery and/or an electrochemical characteristic of the battery.

According to an example, the at least one key datum associated with the signal characteristic of the battery may include a parameter based on an equivalent circuit model of the battery. The signal characteristic of the battery may include characteristics for a single pulse or characteristics for multiple consecutive pulses, which are identified from battery data including the voltage, the current, and the resistance of the battery.

According to an example, the key data associated with the signal characteristic of the battery may include the internal resistance of the battery, the SOH of the battery, the resistance of the charge transfer reaction occurring at an interface between an electrode and an electrolyte, and/or a time constant indicating an interfacial reaction rate between the electrode and the electrolyte.

For example, a single pulse signal may be used for a method for analyzing the response of the battery via a single current pulse. It may be possible to quickly identify, from the single pulse signal, the response of the battery to a specific battery condition.

For example, a multi-pulse signal may be used to identify how the battery responds under different operating conditions by applying consecutive current pulse signals. The multi-pulse signal may be used to predict the performance of the battery in an actual usage environment by precisely reflecting the dynamic characteristics of the battery.

According to an example, if analyzing the response of the battery to a multi-pulse signal, the processor 110 may extract a representative factor among various parameters of a single pulse model. For example, the processor 110 may set/select, as the representative factor, an impedance change at a specific frequency in a multi-pulse interval, and/or a specific resistance value in a charging/discharging cycle.

According to an example, the key data associated with the electrochemical characteristics of the battery may include one or more of a steady-state voltage change, a transient voltage change, and/or a pseudo-diffusivity. Furthermore, the key data associated with the electrochemical characteristics of the battery may include data associated with the number of mobile ions moving at an interface between an electrolyte and an electrode of the battery.

According to an example, the processor 110 may identify (e.g., select, determine), from amongst the at least one key data, the first key data, which may be used to set a criterion associated with failure of the battery. For example, the first key data may include at least one of internal resistance, the SOH of the battery, or any combination thereof. Moreover, the first key data may include data matching two or more key data. As an example, the first key data may include SOH according to the internal resistance.

According to an example, the criterion associated with the failure of the battery may include a criterion for determining that the battery is faulty (e.g., the battery is failed/experiencing failure), a criterion for determining that the battery is at risk of failure (e.g., a risk level of failure), and/or a criterion for determining that the battery is normal (normal operation). The criterion for determining whether a battery is at risk of failure may include a criterion for determining whether there is a potential risk of battery failure.

According to an example, the processor 110 may update, based on the first key data, a multiclass algorithm for performing a diagnosis associated with the failure of the battery.

For example, the processor 110 may update, by using the first key data, the criterion, associated with battery failure, included in the multiclass algorithm.

According to an example, the multiclass algorithm may include an algorithm for a criterion associated with battery failure. That is, the multiclass algorithm may include one or more of an algorithm for a criterion for determining that the battery is faulty, an algorithm for a criterion for determining that the battery is at risk of failure, and/or an algorithm for a criterion for determining that the battery is normal.

According to an example, the multiclass algorithm may include an algorithm for classifying data into one of two or more classes (categories). For example, the multiclass algorithm may be configured to classify data into three or more classes.

According to an example, the multiclass algorithm may include an algorithm for single-label classification, where single input data corresponds to (e.g., only) one class. As another example, a multiclass algorithm may include an algorithm for multi-label classification, where single input data corresponds to a plurality of classes.

According to an example, the processor 110 may perform the diagnosis associated with battery failure based on at least one of: at least one key data, a multiclass algorithm, or any combination thereof.

For example, the processor 110 may determine whether the battery is faulty, at risk of failure, or normal, based on the at least one of: the at least one key data, the multiclass algorithm, or the combination thereof.

As a specific example, the processor 110 may determine whether the battery is faulty, at risk of failure, or normal based on the result of applying the multiclass algorithm to the key data. This is only an example, and the processor 110 may determine various other battery failure cases in addition, or alternative, to the three cases.

According to an example, the processor 110 may update, based on the change rate of first key data, the criterion for determining the failure of the battery, which may be a criterion included in the multiclass algorithm.

According to an example, the processor 110 may calculate/determine a change rate of the first key data. For example, the change rate of the first key data may include the change rate of the SOH of the battery (e.g., determined according to the internal resistance).

According to an example, the processor 110 may determine whether the battery is in a normal state, whether the battery is at risk of failure, or whether the battery is already faulty, by comparing the change rate of the first key data with a predetermined reference change rate.

For example, the multiclass algorithm may include a first reference change rate for determining the battery is at risk of failure, a second reference change rate for determining the battery is faulty, and a third reference change rate for determining the battery is in a normal state.

For example, the processor 110 may update the criterion for determining battery failure based on the change rate of the first key data. The processor 110 may update a reference change rate for determining, based on the change rate of the first key data, that the battery is in a faulty state. The first reference change rate for determining that the battery is at risk of failure, the second reference change rate for determining that the battery is faulty, and/or the third reference change rate for determining that the battery is normal may not be fixed and/or may vary.

According to an example, the processor 110 may identify the first key data to include data associated with at least one of: the internal resistance of the battery, the SOH of the battery, or any combination thereof. For example, the processor 110 may identify the SOH according to/based on the internal resistance of the battery.

According to an example, the processor 110 may calculate/determine at least one of a maximum value, a minimum value, or an average value, or any combination thereof of the change rate of the first key data.

As another example, the processor 110 may calculate/determine the change rate of the first key data within a specific range. For example, if the first key data is SOH (e.g., according to the internal resistance of the battery), the processor 110 may calculate/determine the change rate of the SOH within a range where the internal resistance is 0.002 ohms or more and 0.004 ohms or less. This range is merely an example, and the disclosure is not limited thereto. ○

According to an example, the processor 110 may update a criterion for determining the failure of the battery based on at least one of: a maximum value, a minimum value, an average value, or any combination thereof of the change rate of the first key data.

According to an example, the criterion for determining the failure of the battery may vary depending on the usage environment of the battery. Accordingly, the change rate of the first key data, which serves as the criterion for determining the failure of the battery, may vary/be set according to the usage environment.

According to an example, the processor 110 may compare the first reference change rate for determining that the battery is at risk of failure with the change rate of the first key data. For example, if the first key data outside of the first reference change rate becomes specific volume or more, the processor 110 may update the first reference change rate.

According to an example, the processor 110 may update the criterion for determining the failure of the battery based on the maximum value of the change rate of the first key data.

For example, the criterion for determining the failure of the battery may include a predetermined reference change rate. As a specific example, the criterion for determining battery failure may include the first reference change rate for determining the battery is at risk of failure, the second reference change rate for determining the battery is at a faulty state, or the third reference change rate for determining the battery is at a normal state.

According to an example, the processor 110 may update a criterion for determining the failure of the battery based on at least one of a maximum value of a change rate of the internal resistance, or a maximum value of a change rate of the SOH, or any combination thereof.

According to an example, the processor 110 may determine whether a battery with the same state is faulty by setting a criterion for determining the failure of the battery based on a change rate of key data. The processor 110 may classify batteries based on whether a battery is faulty.

According to an example, the processor 110 may adjust a criterion for determining battery failure for batteries with the same or similar usage cycles.

According to an example, the processor 110 may update at least one of the criterion for determining that the battery is faulty, the criterion for determining that the battery is at risk of failure, or the criterion for determining that the battery is normal, or any combination thereof, which are included in the multiclass algorithm, based on the result of comparing the change rate of the first key data with a predetermined change rate.

According to an example, the predetermined change rate may vary depending on the criterion for determining battery failure. For example, the first reference change rate for determining that the battery is faulty, the second reference change rate for determining that the battery is at risk of failure, and the third reference change rate for determining that the battery is normal may be different from each other.

According to an example, the processor 110 may update the first reference change rate, for determining that the battery is at risk of failure, based on a result of comparing the change rate of the first key data with the second reference change rate for determining that the battery is at risk of failure.

According to an example, the processor 110 may identify, from among at least one key data, second key data that may be used to diagnose battery failure via a multiclass algorithm. For example, the second key data may include a parameter associated with the signal characteristics of the battery, and/or a parameter associated with the electrochemical characteristics of the battery. For example, the second key data may include data used to diagnose the internal state of the battery.

According to an example, the processor 110 may identify the second key data as including data associated with at least one of a change in voltage of the battery, a pseudo-diffusivity associated with the battery, a signal parameter associated with the battery, or an electrochemical parameter associated with the battery, or any combination thereof.

According to an example, the second key data may include a parameter for steady-state voltage changes, a parameter for transient voltage changes, and a parameter for pseudo-diffusivity.

For example, the parameter for steady-state voltage changes may include voltage changes between/based on/in response to external stimuli (currents). The parameter for steady-state voltage changes may be used to understand the long-term performance of the battery and/or to determine maximum efficiency or safe operating ranges.

For example, the parameter for transient voltage changes may include short-term voltage changes in response to external stimuli. Furthermore, the parameter for transient voltage changes may include a parameter indicating the dynamic responsiveness of the battery. The parameter for transient voltage changes may be important/used in evaluating the stability and response speed to rapid power demand changes.

For example, the parameter for pseudo-diffusivity may include a coefficient calculated/determined by simulating a diffusion phenomenon. The parameter for pseudo-diffusivity may include a parameter for indirectly evaluating the mobility of charged materials inside the battery.

According to an example, the processor 110 may identify a time-dependent parameter as the second key data.

According to an example, the processor 110 may identify, among the key data, data necessary for diagnosing battery failure as the second key data.

According to an example, the processor 110 may perform the diagnosis associated with battery failure based on at least one of: the second key data, a multiclass algorithm, or any combination thereof. For example, the processor 110 may perform the diagnosis associated with battery failure based on the result of applying the second key data to the multiclass algorithm.

According to an example, the processor 110 may calculate/determine based on symbolic regression, a symbolic equation by applying key data to a neural network model that updates an equation based on newly input data. For example, the neural network model may include a model that updates, based on the newly input data an equation generated from existing data.

According to an example, the neural network model may include a model to which a symbolic regression method may be applied. The symbolic regression method may include a method of explaining patterns of data by inferring mathematical expressions or functional forms from given data. Unlike the general regression method of finding a function in a specific form that is most suitable for data, the symbolic regression method may include a method of automatically searching for an equation itself, which is most suitable for the data, without predetermining the form or structure of the function.

According to an example, the processor 110 may calculate/determine the symbolic equation by entering the key data into the neural network model. The symbolic equation may be updated (e.g., continuously/repeatedly) by newly input key data.

According to an example, the processor 110 may perform the diagnosis associated with battery failure based on at least one of the key data, the symbolic equation, or the multiclass algorithm, or any combination thereof.

For example, the processor 110 may input the key data into the symbolic equation generated by the neural network model. The input key data may include the first key data. The processor 110 may input a result derived by inputting the key data into the symbolic equation into the multiclass algorithm. The processor 110 may perform the diagnosis associated with battery failure based on the results classified by the multiclass algorithm.

The processor 110 may classify the result values, derived via the symbolic equation, depending on/using: a criterion for determining that the battery is faulty, a criterion for determining that the battery is at risk of failure, and/or a criterion for determining that the battery is normal. The criteria may be included in the multiclass algorithm. The processor 110 may determine, based on the classification result, whether the battery is faulty\.

According to an example, the neural network model may include at least one of a machine learning model, a deep learning model, or any combination thereof.

For example, the neural network model may include a deep neural network model. The neural network model may include one or more of a convolutional neural network (CNN) model, a recurrent neural network (RNN) model, a perceptron, a multilayer perceptron, a feed forward (FF), a radial basis network (RBF) model, a deep feed forward (DFF), a long short term memory (LSTM), a gated recurrent unit (GRU), an auto encoder (AE), a variational auto encoder (VAE), a denoising auto encoder (DAE), a sparse auto encoder (SAE), a Markov chain (MC), a Hopfield network (HN), a Boltzmann machine (BM), a restricted Boltzmann machine (RBM), a deep belief network (DBN) model, a deep convolutional network (DCN), a deconvolutional network (DN) model, a deep convolutional inverse graphics network (DCIGN) model, a generative adversarial network (GAN) model, a liquid state machine (LSM), an extreme learning machine (ELM), an echo state network (ESN) model, a deep residual network (DRN) model, a differentiable neural computer (DNC), a neural turning machine (NTM), a capsule network (CN) model, a Kohonen network (KN) model, and/or an attention network (AN) model.

According to an example, the processor 110 may transmit the result of performing the diagnosis associated with battery failure to at least one of a vehicle including the battery, a device controlling the battery, a device powered by the battery a display for displaying the result and/or information based on the result, a user terminal, or any combination thereof.

According to an example, the result of performing the diagnosis associated with battery failure may include results classified by the multiclass algorithm.

For example, the result of performing the diagnosis associated with battery failure may include a result indicating that the battery is faulty, a result indicating that the battery is at risk of failure, and/or a result indicating that the battery is normal.

According to an example, the vehicle including a battery may display the result of the diagnosis associated with the failure of the battery via the display of the vehicle. For example, the display of the vehicle may include at least one of a cluster, a head-up display (HUD), a center information display (CID), a co-driver display (CDD), a side mirror display, or a rear seat entertainment display, and/or any combination thereof.

According to an example, the device controlling the battery may include a device provided in a device using the battery, or may include a device independent of the device using the battery. For example, a device controlling the battery may include a battery management system (BMS) that monitors and/or manages the condition of the battery in the vehicle (e.g., controls operation of the battery, controls usage of the battery by one or more devices/components of the vehicle, etc.).

According to an example, the result of the diagnosis associated with the failure of the battery may be transmitted to a device controlling the battery, and thus the battery may be efficiently controlled. The performance of the battery may be improved and/or the life of the battery may be increased, by efficiently controlling the battery. For example, the device controlling the battery may switch the battery operation to an power conservation mode, a low power mode, reduce charge/recharge cycles by changing charge/recharge parameters of the battery, control one or more devices powered by the battery to operate by a low power mode and/or switch to an alternative power source, etc.

According to an example, the display that displays the result of performing the diagnosis associated with battery failure may include at least one of a liquid crystal display (LCD), a thin film transistor-liquid crystal display (TFT-LCD), an organic light emitting diode (OLED) display, a flexible display, a field emission display (FED), and/or a 3D display.

According to an example, the processor 110 may provide a user with information associated with the condition of the battery by displaying the result of the diagnosis associated with the failure of the battery on the display.

According to an example, the processor 110 may determine whether key variables included in an equation (e.g., a symbolic equation determined based on symbolic regression) are capable of indicating a specific condition of the battery. The processor 110 may interpret, via a symbolic regression process, characteristics associated with the key variables in the equation to determine whether the key variables are capable of indicating the specific condition.

For example, if a specific resistance value corresponding to a specific section of the SOC is capable of indicating a fault condition of the battery (e.g., is learned to correspond to/correlate with the fault condition), the processor 110 may identify the specific resistance value in the specific section of the SOC as a key variable. Accordingly, the processor 110 may perform the diagnosis associated with battery failure based on the specific resistance value in the specific section of the SOC. The specific section of the SOC may be determined by user or system.

According to an example, the processor 110 may identify a key variable based on at least one of SOC, a temperature, a voltage, and/or any combination thereof. The key variable may play an important role in predicting battery failure.

According to an example, the processor 110 may extract physical meaning essential for the diagnosis associated with battery failure based on the key variable. The processor 110 may generate the diagnosis results, to which the physical meaning essential for diagnosing battery failure is reflected, and/or may provide information including the diagnosis results via the display.

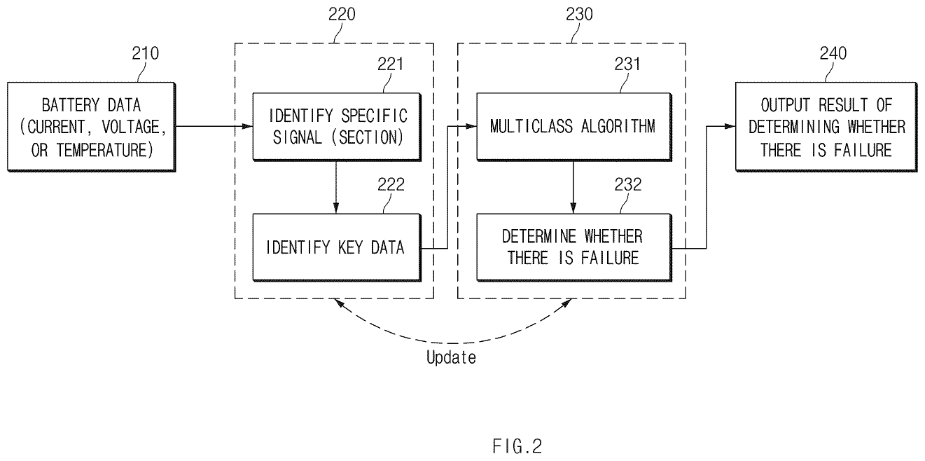

FIG. 2 is a drawing showing an example of a process in which a battery diagnosing apparatus determines whether a battery is faulty, according to an example of the present disclosure. For convenience, FIG. 2 is described by way of an example in which the steps are performed by a processor circuit of the battery diagnosing apparatus 100 (e.g., processor 110). One, some, or all steps of the example method of FIG. 2, or portions thereof, may be performed by one or more other circuits. One or more steps of the example method of FIG. 2 may be omitted, performed in other orders, and/or otherwise modified, and/or one or more additional steps may be added.

According to an example, a battery diagnosing apparatus 100 may identify data associated with a battery (210). The data associated with the battery may include data associated with (e.g., based on) a current, a voltage, or a temperature. For example, the battery diagnosing apparatus may identify data associated with the battery by using a voltage sensor, a current sensor, a temperature sensor, or the like.

According to an example, the battery diagnosing apparatus may perform a diagnosis associated with battery failure via at least one of process 220 of preprocessing data, or process 230 of applying data to a model for diagnosing battery failure, or any combination thereof.

According to an example, the battery diagnosing apparatus may identify a specific signal (e.g., a specific section/interval of the signal) based on/of/in the data associated with the battery (221).

According to an example, the battery diagnosing apparatus may identify at least one key data associated with a signal characteristic of the battery (e.g., a characteristic of the specific signal) or an electrochemical characteristic of the battery based on the specific signal (the specific section/interval) (222).

According to an example, the battery diagnosing apparatus may classify, via a multiclass algorithm, key data (231). For example, the battery diagnosing apparatus may input the key data into a neural network model including a symbolic equation based on symbolic regression. The battery diagnosing apparatus may classify, by using a multiclass algorithm, the results calculated/determined via the neural network model. For example, the battery diagnosing apparatus may input the result value, calculated/determined by entering the key data into a symbolic equation, into the multiclass algorithm.

According to an example, the battery diagnosing apparatus may determine, based on the result classified by the multiclass algorithm, whether the battery is faulty (232). For example, the battery diagnosing apparatus may determine whether the battery is normal, whether the battery is at risk of failure, or whether the battery is already faulty, based on the result classified by the multiclass algorithm.

According to an example, the battery diagnosing apparatus may update, by using the key data, the multiclass algorithm. For example, the battery diagnosing apparatus may include first key data, which may be used to set a criterion associated with the failure of the battery, from among at least one key data. As a specific example, the first key data may include at least one of internal resistance, the SOH of the battery, and/or any combination thereof.

According to an example, the battery diagnosing apparatus may output, on a display, the result of determining whether the battery is faulty (240). In this case, the display may include at least one of a display of a device using a battery, a display of a device diagnosing a battery, and/or a display of a user's terminal, or any combination thereof.

According to an example, the battery diagnosing apparatus may transmit, to the device controlling the battery, the result of determining whether the battery is faulty. The device controlling the battery may control the battery based on the result of determining whether the battery is faulty.

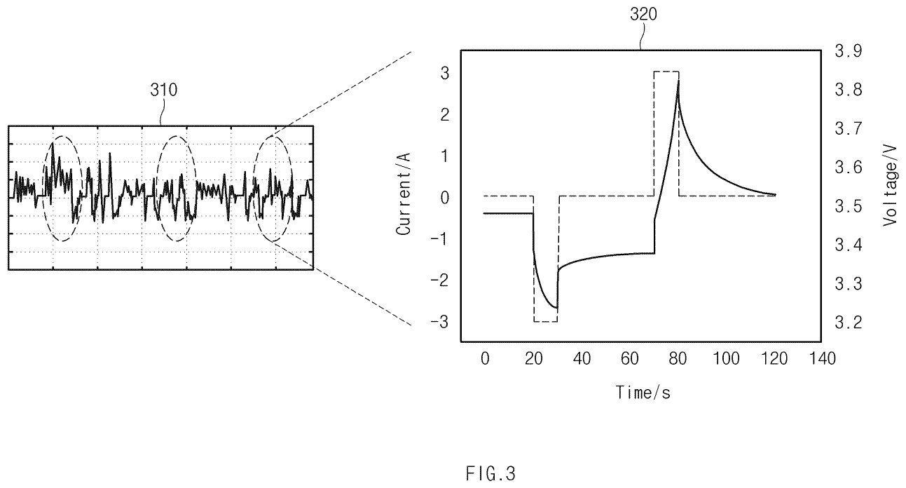

FIG. 3 is a drawing showing an example of a pulse-based analysis technique associated with a battery diagnosing apparatus, according to an example of the present disclosure.

According to an example, a battery diagnosing apparatus may identify battery-related data as pulse-type data 310.

For example, data collected from the BMS of a vehicle may be organized into various pulse formats. The pulse data may include various pieces of information indicating a battery condition, in addition to information about a simple voltage, a simple temperature, and/or a simple current. Each pulse data may indicate a specific stage of the battery charging and/or discharging process. The pulse data may provide an important indicator of the performance, the safety, and/or the lifespan of the battery.

According to an example, the battery diagnosing apparatus may analyze data associated with the battery based on the pulse-type data 310 (320).

A technology for analyzing data based on the pulse-type data 310 may include a technology for identifying a specific signal section/interval within pulse data and diagnosing a battery condition by analyzing data included in the specific signal section. The technology for analyzing data based on the pulse-type data 310 may perform more accurate and efficient diagnosis than a technology for simply analyzing data (e.g., static data), and may be utilized to identify complex electrochemical characteristics inside the battery.

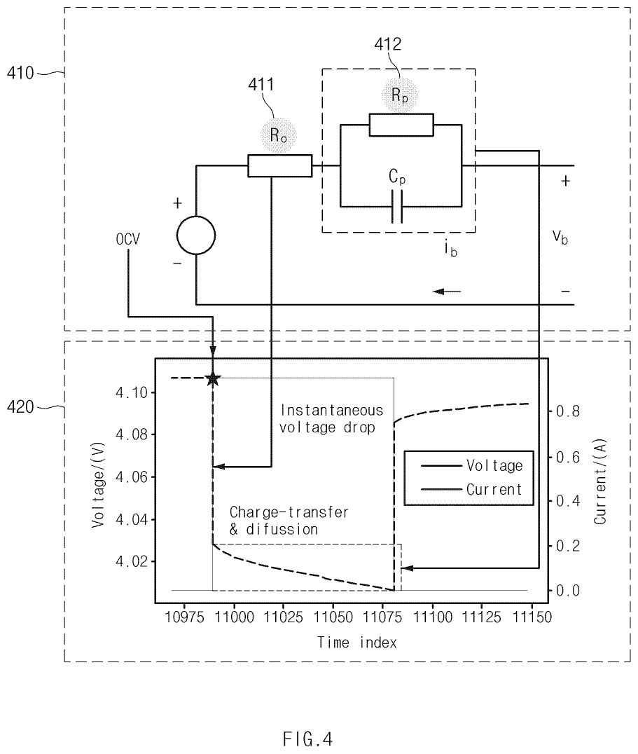

FIG. 4 is a drawing for describing an example of signal characteristics of a battery associated with a battery diagnosing apparatus, according to an example of the present disclosure.

According to an example, a factor associated with signal characteristics of a battery may include a parameter of an equivalent circuit model of the battery. The factor associated with the signal characteristics of the battery may be applied to a single pulse and/or to multiple consecutive pulses. Moreover, a parameter of a single pulse may also be extracted from multiple pulses.

FIG. 4 shows an example equivalent circuit 410 associated with a battery and a graph 420 of a voltage measured by the equivalent circuit 410.

According to an example, the equivalent circuit 410 associated with the battery may include an ohmic resistor 411 and/or a charge transfer resistor 412.

According to an example, the ohmic resistor 411 may include/represent the internal resistance of the battery. The ohmic resistor 411 may include/be implemented as a resister configured to account for the drop or rise of an initial voltage that occurs if a current flows. For example, as the resistance of the ohmic resistor 411 is large, power loss may increase, battery efficiency may decrease, and/or heat may be generated.

According to an example, the charge transfer resistor 412 may include/represent resistance to a charge transfer reaction occurring at an interface between an electrode and an electrolyte. The charge transfer resistor 412 may affect the charging/discharging speed of the battery. If the resistance of the charge transfer resistor 412 is large, charges move slowly, which may indicate a slow electrochemical reaction in the battery cell.

According to an example, a charge transfer time constant may be calculated/determined based on the charge transfer resistor 412 and a capacitor capable of being connected in parallel with the charge transfer resistor 412. For example, the charge transfer time constant may include a time constant indicating an interfacial reaction rate between the electrode and the electrolyte. For example, the charge transfer time constant may indicate the time required to reach a new equilibrium state in response to a change in current. As the charge transfer time constant is small, the reaction speed of the system may be fast. As the reaction speed of the battery is fast, the charging or discharging speed of the battery may be fast.

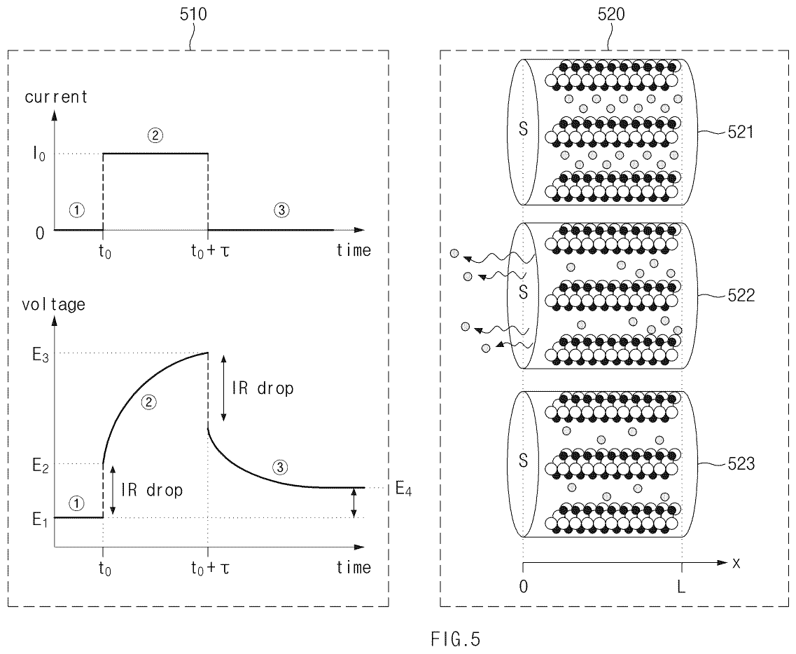

FIG. 5 is a drawing for describing an example of electrochemical characteristics of a battery associated with a battery diagnosing apparatus, according to an example of the present disclosure.

According to an example, a factor associated with the electrochemical characteristics of a battery may be an important indicator for evaluating the electrochemical characteristics inside the battery.

According to an example, the factor associated with the electrochemical characteristics of a battery may include a parameter for steady-state voltage changes, a parameter for transient voltage changes, and a parameter for pseudo-diffusivity.

FIG. 5 according to an example may include a graph showing a change in current of a battery over time and a graph showing a change in voltage of the battery over time (510).

The graph showing the change in current of the battery of FIG. 5 may include section \textcircled{1} before a current is applied until time t0, section \textcircled{2} where a constant current I0 is applied for duration τ from time t0, and section \textcircled{3} where the constant current I0 is no longer applied.

The graph showing the change in voltage of the battery in FIG. 5 may include section \textcircled{1} where a voltage is constant until time t0, section \textcircled{2} where the voltage increases while the constant current I0 is applied, and section \textcircled{3} where the voltage decreases if the constant current I0 is no longer applied.

For example, sections \textcircled{1}, \textcircled{2}, and \textcircled{3} of the graph showing changes in current of the battery may correspond to sections \textcircled{1}, \textcircled{2}, and \textcircled{3} of the graph showing changes in voltage of the battery.

FIG. 5 according to an example illustrates a phenomenon in which ions diffuse according to changes in current and/or voltage of the battery (520).

For example, in section \textcircled{1} before a current is applied, an equilibrium state may be maintained (521). The voltage in this section may be constant as E1.

For example, in section \textcircled{2} where a constant current is applied, ions may diffuse (522). The voltage in this section may vary from E1 to E2.

For example, in section \textcircled{3} where the constant current is no longer applied, a new equilibrium state may be reached after sufficient relaxation time elapses. The voltage in this section may vary to E4, and E4 may be a different voltage level than E1 and/or E2.

Referring to FIG. 5 according to an example, voltage and/or ion diffusion coefficient may vary depending on the current applied to the battery (and/or history of current applied to the battery). The battery diagnosing apparatus 100 may perform a diagnosis associated with battery failure based on parameters associated with changes in: the current, the voltage, and/or the ion diffusion coefficient.

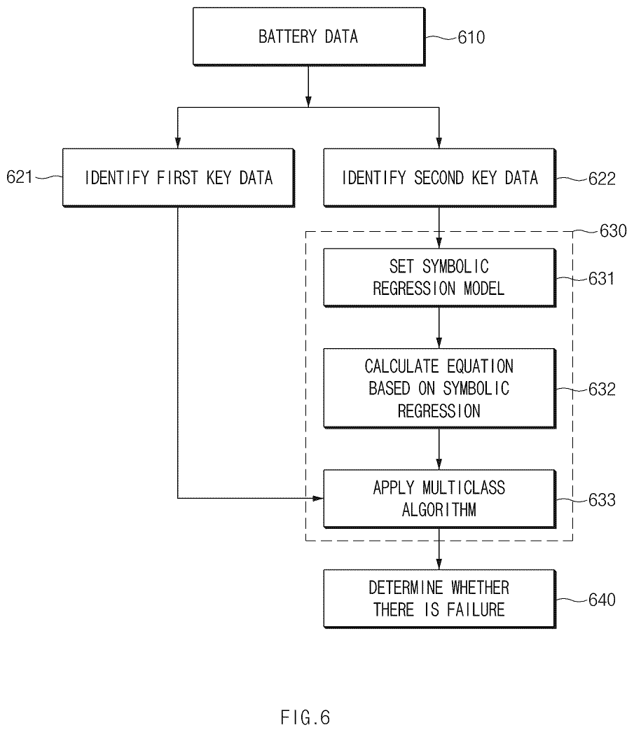

FIG. 6 is a diagram showing an example of a process, in which a battery diagnosing apparatus determines whether a battery is faulty by using a multiclass algorithm, according to an example of the present disclosure. For convenience, FIG. 6 is described by way of an example in which the steps are performed by a processor circuit of the battery diagnosing apparatus 100 (e.g., processor 110). One, some, or all steps of the example method of FIG. 6, or portions thereof, may be performed by one or more other circuits. One or more steps of the example method of FIG. 6 may be omitted, performed in other orders, and/or otherwise modified, and/or one or more additional steps may be added.

According to an example, a battery diagnosing apparatus 100 may identify data associated with a battery (610).

According to an example, the battery diagnosing apparatus 100 may identify key data about the battery associated with the signal characteristics of the battery or the electrochemical characteristics of the battery.

For example, the battery diagnosing apparatus 100 may identify first key data, which may be used to set a criterion associated with the failure of the battery, from among at least one key data (621). For example, the first key data may include at least one of internal resistance, or the SOH of the battery, or any combination thereof.

According to an example, the battery diagnosing apparatus may update the multiclass algorithm by using the first key data. The multiclass algorithm may include an algorithm for a criterion associated with battery failure. Accordingly, the battery diagnosing apparatus may update a criterion associated with battery failure by using the first key data.

For example, the battery diagnosing apparatus may identify second key data used to diagnose battery failure via a multiclass algorithm (622). For example, the second key data may include a parameter associated with the signal characteristics of the battery, and/or a parameter associated with the electrochemical characteristics of the battery.

According to an example, the battery diagnosing apparatus may apply second key data to a model for diagnosing battery failure (630).

According to an example, the model for diagnosing battery failure may include process 631 of setting up a symbolic regression model, process 632 of calculating/determining an equation based on symbolic regression, and process 633 of applying a multiclass algorithm.

According to an example, the battery diagnosing apparatus may set a neural network model that updates an equation based on newly input data. For example, the battery diagnosing apparatus may set the symbolic regression model (631).

According to an example, the battery diagnosing apparatus may calculate/determine a symbolic equation based on the symbolic regression model (632).

According to an example, the battery diagnosing apparatus may input the second key data into the symbolic equation. The battery diagnosing apparatus may identify the result value calculated/determined by inputting the second key data into the symbolic equation.

According to an example, the battery diagnosing apparatus may input the result value, calculated/determined using the symbolic equation, into the multiclass algorithm (633). For example, the battery diagnosing apparatus may classify, by using the multiclass algorithm, the results calculated/determined using the symbolic equation.

According to an example, the battery diagnosing apparatus may, based on the result of classifying the results calculated/determined by the symbolic equation classified via the multiclass algorithm, perform a diagnosis associated with battery failure (640).

For example, the battery diagnosing apparatus may determine, based on the results classified by the multiclass algorithm, whether the battery is faulty, whether the battery is at risk of failure, or whether the battery is normal.

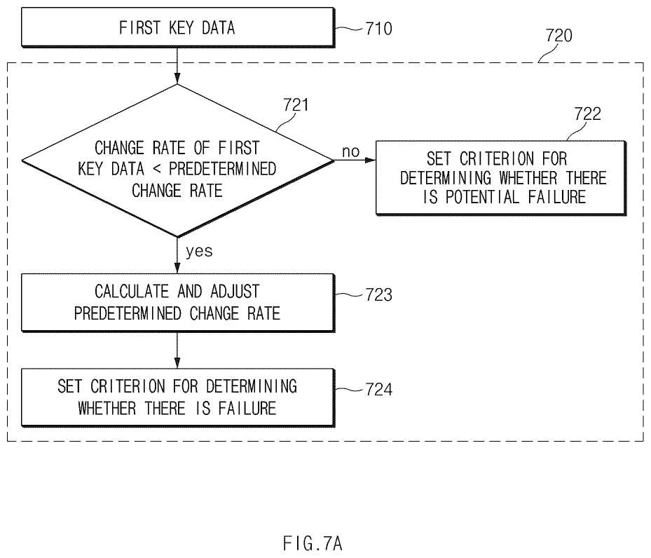

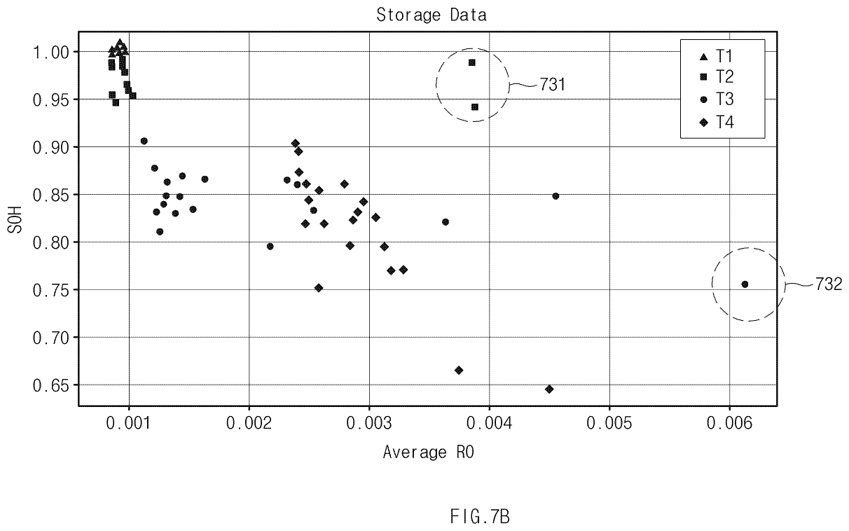

FIG. 7A is a diagram illustrating an example, in which a battery diagnosing apparatus updates a multiclass algorithm by using first key data, according to an example of the present disclosure. For convenience, FIG. 7A is described by way of an example in which the steps are performed by a processor circuit of the battery diagnosing apparatus 100 (e.g., processor 110). One, some, or all steps of the example method of FIG. 7A, or portions thereof, may be performed by one or more other circuits. One or more steps of the example method of FIG. 7A may be omitted, performed in other orders, and/or otherwise modified, and/or one or more additional steps may be added.

According to an example, a battery diagnosing apparatus may identify first key data, used to set a criterion associated with the failure of the battery, from among at least one key data (710).

According to an example, the battery diagnosing apparatus may update the multiclass algorithm by using the first key data (720).

According to an example, the battery diagnosing apparatus may compare a change rate of the first key data with a predetermined change rate (721). For example, the battery diagnosing apparatus may determine whether the change rate of the first key data is less than the predetermined change rate.

According to an example, if the change rate of the first key data is not less than the predetermined change rate, the battery diagnosing apparatus may set/adjust a criterion for determining whether there is potential failure (722). For example, if the change rate of the first key data is greater than the predetermined change rate, the battery diagnosing apparatus may determine that the battery is at risk of failure.

According to an example, if the change rate of the first key data is less than the predetermined change rate, the battery diagnosing apparatus may calculate/determine and/or adjust the predetermined change rate (723). For example, the predetermined change rate may be adjusted based on a range in which the first key data is changed.

According to an example, the battery diagnosing apparatus may set a criterion for determining whether there is failure (724). For example, the battery diagnosing apparatus may set/adjust, based on the range in which the first key data is changed, a criterion for determining that a battery is faulty. As a specific example, the battery diagnosing apparatus may set a change rate of a criterion for determining that the battery is faulty.

Referring to FIG. 7A according to an example, the battery diagnosing apparatus may update a multiclass algorithm by using the first key data, thereby improving the accuracy of a diagnosis associated with battery failure.

FIG. 7B is a graph showing the distribution of key data that a battery diagnosing apparatus according to an example of the present disclosure identifies to determine whether there is potential failure.

FIG. 7B according to an example shows a graph of the SOH of a battery according to average resistance R0.

The graph of FIG. 7B according to an example may include data associated with SOH identified depending on a period in which the battery is used.

For example, the graph in FIG. 7B shows information about experimental groups identified depending on the period in which the battery is used. In particular, a period from the beginning of a test to the end of the test was split into a period of four stages. For example, the four stages in the period are specified as T1, T2, T3, and T4, respectively.

Referring to the graph of FIG. 7B according to an example, some pieces of data out of a range in which the pieces of data T2 is changed are identified (731). For example, the corresponding pieces of data may be identified as pieces of data that deviate from (e.g., are statistical outliers from) a predetermined change rate with respect to the pieces of data T2.

Referring to the graph of FIG. 7B according to an example, some pieces of data out of a range in which the pieces of data T3 are changed may be identified (732) (e.g., 732 points out a statistical outlier of data points from stage T3). For example, the corresponding piece of data is identified as a piece of data that deviates from (e.g., is an outlier from) a predetermined change rate with respect to the pieces of data T3.

According to an example, if data 731 and data 732 (e.g., outliers that deviates from corresponding predetermined change rates) are identified, the battery diagnosing apparatus may determine that the corresponding battery is potentially at risk of failure.

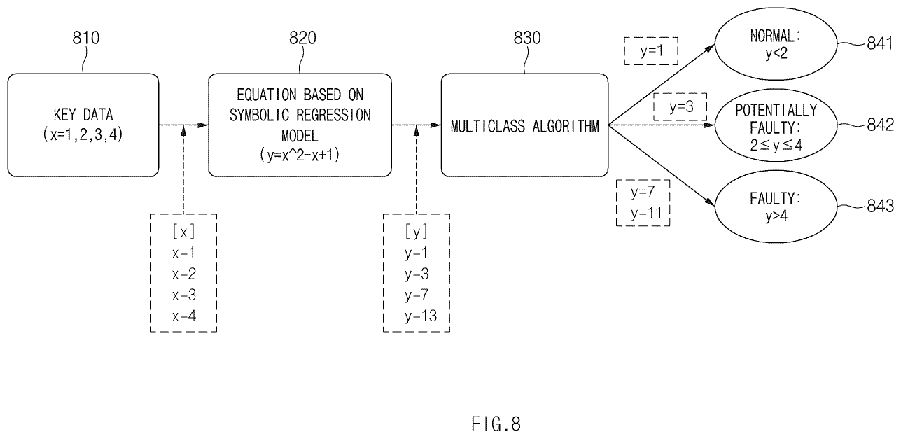

FIG. 8 is a drawing showing an example of a specific process, in which a battery diagnosing apparatus determines whether a battery is faulty by using a symbolic equation and a multiclass algorithm, according to an example of the present disclosure.

According to an example, a battery diagnosing apparatus may identify key data from data associated with a battery (810).

Hereinafter, values ‘x’ of four pieces of key data identified by the battery diagnosing apparatus may be assumed to be 1, 2, 3, and 4, respectively.

According to an example, the battery diagnosing apparatus may input the key data into a symbolic equation generated based on a symbolic regression model (820).

For example, the symbolic equation may be expressed as “y=x²−x+1”. In this case, the battery diagnosing apparatus may input 1, 2, 3, and 4, which are the values ‘x’ of the key data, into the symbolic equation. The battery diagnosing apparatus may identify result values ‘y’, which are obtained by inputting 1, 2, 3, and 4 corresponding to the values ‘x’ of the key data into the symbolic equation, as 1, 3, 7, and 13, respectively.

According to an example, the battery diagnosing apparatus may input the result values ‘y’ input into the symbolic equation into a multiclass algorithm (830).

According to an example, the multiclass algorithm may include a criterion for determining that the battery is faulty, a criterion for determining that the battery is at risk of failure, and a criterion for determining that the battery is normal.

For example, the criterion for determining that a battery is normal may include a case where an input value is less than 2 (841). Accordingly, if the value input to the multiclass algorithm is less than 2, the battery may be determined as being normal.

For example, the criterion for determining whether a battery is potentially at risk of failure may include a case where the input value is greater than or equal to 2 and less than or equal to 4 (842). Accordingly, if the value input to the multiclass algorithm is 2 or more and 4 or less (e.g., between 2 and 4, inclusive), the battery may be determined to be at risk of potential failure.

For example, the criterion for determining that a battery is faulty may include a case where the input value exceeds 4 (843). Accordingly, if the value input to the multiclass algorithm exceeds 4, the battery may be determined as being faulty. The range boundaries are solely for example, and are not limiting to the present disclosure.

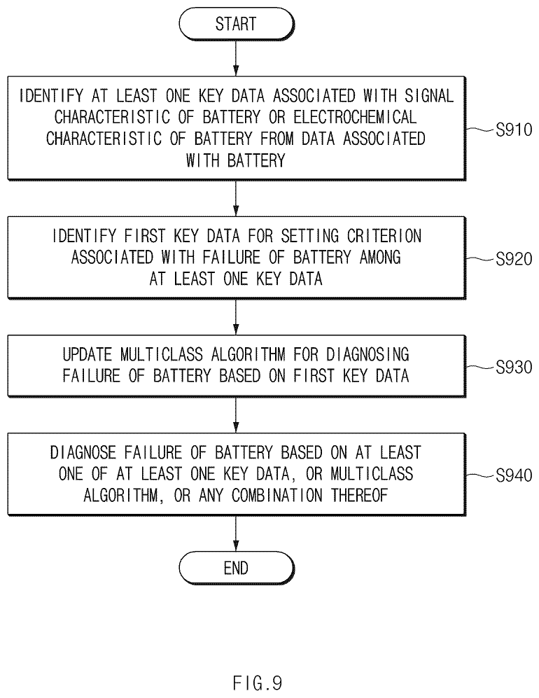

FIG. 9 is a flowchart for describing a battery diagnosing apparatus or a battery diagnosing method, according to an example of the present disclosure. For convenience, FIG. 9 is described by way of an example in which the steps are performed by a processor circuit of the battery diagnosing apparatus 100 (e.g., processor 110). One, some, or all steps of the example method of FIG. 9, or portions thereof, may be performed by one or more other circuits. One or more steps of the example method of FIG. 9 may be omitted, performed in other orders, and/or otherwise modified, and/or one or more additional steps may be added.

Hereinafter, a battery diagnosing apparatus or a battery diagnosing method according to an example of the present disclosure will be specifically described with reference to FIG. 9.

Hereinafter, the battery diagnosing apparatus 100 of FIG. 1 may perform the process of FIG. 9. In addition, in a description of FIG. 9, it may be understood that an operation described as being performed by a battery diagnosing apparatus is controlled by the processor 110 of the battery diagnosing apparatus 100. However, one, some, or all steps of the example method of FIG. 9, or portions thereof, may be performed by one or more other circuits. One or more steps of the example method of FIG. 9 may be omitted, performed in other orders, and/or otherwise modified, and/or one or more additional steps may be added.

According to an example, the processor of the battery diagnosing apparatus may identify, from data associated with a battery, at least one key data associated with a signal characteristic of the battery or an electrochemical characteristic of the battery (S910).

According to an example, the processor of the battery diagnosing apparatus may identify first key data for setting a criterion associated with the failure of the battery among at least one key data (S920).

According to an example, the processor of the battery diagnosing apparatus may update a multiclass algorithm for diagnosing the failure/operation status of the battery based on the first key data (S930).

According to an example, the processor of the battery diagnosing apparatus may diagnose the failure of the battery based on at least one of at least one key data, or a multiclass algorithm, or any combination thereof (S940).

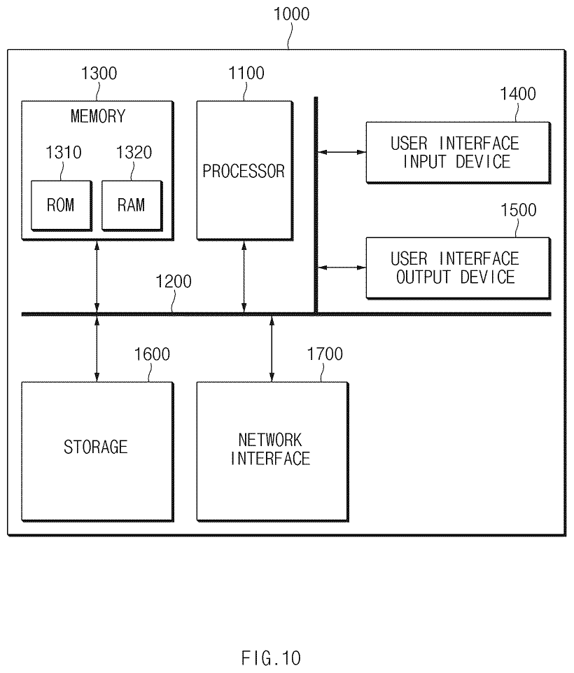

FIG. 10 is a diagram showing a computing system associated with a battery diagnosing apparatus or a battery diagnosing method, according to an example of the present disclosure.

Referring to FIG. 10, a computing system 1000 may include at least one processor 1100, a memory 1300, a user interface input device 1400, a user interface output device 1500, storage 1600, and a network interface 1700, which are connected with each other via a bus 1200.

The processor 1100 may be a central processing unit (CPU) or a semiconductor device that processes instructions stored in the memory 1300 and/or the storage 1600. Each of the memory 1300 and the storage 1600 may include various types of volatile or nonvolatile storage media. For example, the memory 1300 may include a read only memory (ROM) 1310 and a random access memory (RAM) 1320.

Accordingly, the operations of the method or algorithm described in connection with examples disclosed in the specification may be directly implemented with a hardware module, a software module, or a combination of the hardware module and the software module, which is executed by the processor 1100. The software module may reside on a storage medium (i.e., the memory 1300 and/or the storage 1600) such as a random access memory (RAM), a flash memory, a read only memory (ROM), an erasable and programmable ROM (EPROM), an electrically EPROM (EEPROM), a register, a hard disk drive, a removable disc, or a compact disc-ROM (CD-ROM).

The storage medium may be coupled to the processor 1100. The processor 1100 may read out information from the storage medium and may write information in the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

The above description is merely an example of the technical idea of the present disclosure, and various modifications and variations may be made by one skilled in the art without departing from the essential characteristic of the present disclosure.

The present disclosure was made to solve the above-mentioned problems occurring in the prior art while advantages achieved by the prior art are maintained intact.

The present disclosure provides a battery diagnosing apparatus that may effectively identify faults occurring in an environment, in which a battery is actually operated, by performing a diagnosis associated with the failure of the battery based on an electrochemical reaction mechanism of the battery, and a method thereof.

According to the present disclosure, a battery diagnosing apparatus may immediately diagnose battery failure by monitoring the condition of the battery in real time, and thus may early identify issues occurring in a battery system, and a method thereof.

According to the present disclosure, a battery diagnosing apparatus may be applied to various types of battery systems, not limited to Li-ion batteries, and thus may be flexibly utilized in technologies for various types of batteries, and a method thereof.

According to the present disclosure, a battery diagnosing apparatus may be robustly applied to various pieces of driving data via a cloud-based structure, and thus may stably respond to data variability in an actual operating environment, and a method thereof.

According to the present disclosure, a battery diagnosing apparatus may increase safety and may minimize the possibility that an accident occurs, by detecting battery failure in advance to reduce the risk of explosion, fire, and the like, and a method thereof.

The technical problems to be solved by the present disclosure are not limited to the aforementioned problems, and any other technical problems not mentioned herein will be clearly understood from the following description by those skilled in the art to which the present disclosure pertains.

According to the present disclosure, a battery diagnosing apparatus includes a memory that stores a program instruction, and a processor that executes the program instruction. The processor identifies at least one key data associated with a signal characteristic of a battery or an electrochemical characteristic of the battery from data associated with the battery, identifies first key data, which is used to set a criterion associated with failure of the battery, from among the at least one key data, updates a multiclass algorithm for performing a diagnosis associated with the failure of the battery based on the first key data, and performs the diagnosis associated with the failure of the battery based on at least one of at least one key data, or the multiclass algorithm, or any combination thereof.

The processor may update a criterion for determining the failure of the battery, which is included in the multiclass algorithm, based on a change rate of first key data.

The processor may identify the first key data including data associated with at least one of internal resistance of the battery, or state-of-health (SOH) of the battery, or any combination thereof, and may update the criterion for determining the failure of the battery based on at least one of a maximum value of a change rate of the internal resistance, or a maximum value of a change rate of the SOH, or any combination thereof.

The processor may update at least one of a criterion for determining that the battery is faulty, a criterion for determining that the battery is at risk of failure, or a criterion for determining that the battery is normal, or any combination thereof, which are included in the multiclass algorithm, based on a result of comparing a change rate of the first key data with a predetermined change rate.

The processor may identify second key data, which is used to diagnose the failure of the battery via the multiclass algorithm, from among the at least one key data, and may perform the diagnosis associated with the failure of the battery based on at least one of the second key data, or the multiclass algorithm, or any combination thereof.

The processor may identify the second key data including data associated with at least one of a change in voltage of the battery, a pseudo-diffusivity associated with the battery, a signal parameter associated with the battery, or an electrochemical parameter associated with the battery, or any combination thereof.

The processor may calculate a symbolic equation based on symbolic regression by applying the key data to a neural network model that updates an equation based on newly input data.

The processor may perform the diagnosis associated with the failure of the battery based on at least one of the key data, the symbolic equation, or the multiclass algorithm, or any combination thereof.

The neural network model may include at least one of a machine learning model, or a deep learning model, or any combination thereof.

The processor may transmit a result of performing the diagnosis associated with the failure of the battery to at least one of a vehicle including the battery, a device controlling the battery, a display displaying the result, or a user terminal, or any combination thereof.

According to an aspect of the present disclosure, a battery diagnosing method includes identifying, by a processor, at least one key data associated with a signal characteristic of a battery or an electrochemical characteristic of the battery from data associated with the battery, identifying, by the processor, first key data, which is used to set a criterion associated with failure of the battery, from among the at least one key data, updating, by the processor, a multiclass algorithm for performing a diagnosis associated with the failure of the battery based on the first key data, and performing, by the processor, the diagnosis associated with the failure of the battery based on at least one of at least one key data, or the multiclass algorithm, or any combination thereof.

The updating, by the processor, of the multiclass algorithm for performing the diagnosis associated with the failure of the battery based on the first key data may include updating, by the processor, a criterion for determining the failure of the battery, which is included in the multiclass algorithm, based on a change rate of first key data.

The identifying, by the processor, of the first key data, which is used to set the criterion associated with the failure of the battery, from among the at least one key data may include identifying, by the processor, the first key data including data associated with at least one of internal resistance of the battery, or SOH of the battery, or any combination thereof. The updating, by the processor, of the multiclass algorithm for performing the diagnosis associated with the failure of the battery based on the first key data may include updating, by the processor, the criterion for determining the failure of the battery based on at least one of a maximum value of a change rate of the internal resistance, or a maximum value of a change rate of the SOH, or any combination thereof.

The updating, by the processor, of the multiclass algorithm for performing the diagnosis associated with the failure of the battery based on the first key data may include updating, by the processor, at least one of a criterion for determining that the battery is faulty, a criterion for determining that the battery is at risk of failure, or a criterion for determining that the battery is normal, or any combination thereof, which are included in the multiclass algorithm, based on a result of comparing a change rate of the first key data with a predetermined change rate.

The battery diagnosing method may further include identifying, by the processor, second key data, which is used to diagnose the failure of the battery via the multiclass algorithm, from among the at least one key data. The performing, by the processor, of the diagnosis associated with the failure of the battery based on the at least one of the at least one key data, or the multiclass algorithm, or any combination thereof may include performing, by the processor, the diagnosis associated with the failure of the battery based on at least one of the second key data, or the multiclass algorithm, or any combination thereof.

The identifying, by the processor, of the second key data, which is used to diagnose the failure of the battery via the multiclass algorithm, from among the at least one key data may include identifying, by the processor, the second key data including data associated with at least one of a change in voltage of the battery, a pseudo-diffusivity associated with the battery, a signal parameter associated with the battery, or an electrochemical parameter associated with the battery, or any combination thereof.

The performing, by the processor, of the diagnosis associated with the failure of the battery based on the at least one of the at least one key data, or the multiclass algorithm, or any combination thereof may include calculating, by the processor, a symbolic equation based on symbolic regression by applying the key data to a neural network model that updates an equation based on newly input data.

The performing, by the processor, of the diagnosis associated with the failure of the battery based on the at least one of the at least one key data, or the multiclass algorithm, or any combination thereof may include performing, by the processor, the diagnosis associated with the failure of the battery based on at least one of the key data, the symbolic equation, or the multiclass algorithm, or any combination thereof.

The neural network model may include at least one of a machine learning model, or a deep learning model, or any combination thereof.

The battery diagnosing method may further include transmitting, by the processor, a result of performing the diagnosis associated with the failure of the battery to at least one of a vehicle including the battery, a device controlling the battery, a display displaying the result, or a user terminal, or any combination thereof.

Accordingly, examples of the present disclosure are intended not to limit but to explain the technical idea of the present disclosure, and the scope and spirit of the present disclosure is not limited by the above examples. The scope of protection of the present disclosure should be construed by the attached claims, and all equivalents thereof should be construed as being included within the scope of the present disclosure.

The present technology may effectively identify faults occurring in an environment, in which a battery is actually operated, by performing a diagnosis associated with the failure of the battery based on an electrochemical reaction mechanism of the battery.

Moreover, the present technology may immediately diagnose battery failure by monitoring the condition of the battery in real time, and thus may early identify issues occurring in a battery system.

Furthermore, the present technology may be applied to various types of battery systems, not limited to Li-ion batteries, and thus may be flexibly utilized in technologies for various types of batteries.

Also, the present technology may be robustly applied to various pieces of driving data via a cloud-based structure, and thus may stably respond to data variability in an actual operating environment.

In addition, the present technology may increase safety and may minimize the possibility that an accident occurs, by detecting battery failure in advance to reduce the risk of explosion, fire, and the like.

In addition, a variety of effects directly or indirectly understood via the present disclosure may be provided.

Hereinabove, although the present disclosure was described with reference to examples and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. A battery management apparatus comprising:
a memory configured to store one or more instructions; and
a processor configured to execute the one or more instructions,
wherein the processor, by executing the one or more instructions, is configured to cause the battery management apparatus to:
receive, from one or more sensors, data associated with a physical state of the battery;
identify, based on the data, at least one key data associated with:
a signal characteristic of the battery, or
an electrochemical characteristic of the battery;
identify first key data, from among the at least one key data, for setting a criterion associated with failure of the battery;
update, based on the first key data, a multiclass algorithm for performing a diagnosis associated with a failure state of the battery;
diagnose, based on at least one of the at least one key data or the multiclass algorithm, the failure state of the battery; and
control, based on the diagnosed failure state of the battery, usage of the battery.

2. The battery management apparatus of claim 1, wherein the processor is configured to cause the battery management apparatus to:
update, based on a change rate of the first key data, a criterion, of the multiclass algorithm, for determining the failure of the battery.

3. The battery management apparatus of claim 2, wherein the processor is configured to cause the battery management apparatus to:
identify the first key data as comprising data associated with at least one of:
an internal resistance of the battery, or
a state-of-health (SOH) of the battery; and
update, based on a change rate of the first key data, the criterion for determining the failure of the battery.

4. The battery management apparatus of claim 1, wherein the processor is configured to cause the battery management apparatus to:
update, based on a comparison between a change rate of the first key data and a predetermined change rate, at least one criterion selected from:
a criterion for determining that the battery is faulty,
a criterion for determining that the battery is at risk of failure, or
a criterion for determining that the battery is normal,
wherein the at least one criterion is of the multiclass algorithm.

5. The battery management apparatus of claim 1, wherein the processor is configured to cause the battery management apparatus to:
identify, from among the at least one key data, second key data for use in diagnosing the failure of the battery via the multiclass algorithm; and
perform, based on at least one of the second key data or the multiclass algorithm, the diagnosis associated with the failure of the battery.

6. The battery management apparatus of claim 5, wherein the processor is configured to cause the battery management apparatus to:
identify the second key data as comprising data associated with at least one of:
a change in voltage of the battery,
a pseudo-diffusivity associated with the battery,
a signal parameter associated with the battery, or
an electrochemical parameter associated with the battery.

7. The battery management apparatus of claim 1, wherein the processor is configured to cause the battery management apparatus to:
apply the first key data to a neural network model that updates an equation based on newly input data to determine, by symbolic regression, a symbolic equation; and
update, based on the symbolic equation, the multiclass algorithm.

8. The battery management apparatus of claim 7, wherein the processor is configured to cause the battery management apparatus to:
diagnose the failure state of the battery based on at least one of:
the key data,
the symbolic equation, or
the multiclass algorithm.

9. The battery management apparatus of claim 7, the neural network model comprises at least one of: a machine learning model or a deep learning model.

10. The battery management apparatus of claim 1, wherein the processor is configured to cause the battery management apparatus to:
transmit the diagnosed failure state of the battery to at least one of:
a vehicle comprising the battery,
a device controlling the battery,
a display displaying the diagnosed failure state, or
a user terminal,
wherein the failure state indicates one or more of:
failure of the battery;
a risk level of failure of the battery; or
normal operation of the battery.

11. A method performed by an apparatus of a vehicle, the method comprising:
receiving, from one or more sensors, data associated with a physical state of a battery of the vehicle;
identifying, by a processor circuit and based on the data, at least one key data associated with:
a signal characteristic of the battery, or
an electrochemical characteristic of the battery;
identifying, by the processor circuit and from among the at least one key data, first key data for setting a criterion associated with failure of the battery;
updating, by the processor circuit and based on the first key data, a multiclass algorithm for performing a diagnosis associated with a failure state of the battery;
diagnosing, by the processor circuit and based on at least one of the at least one key data or the multiclass algorithm, the failure state of the battery; and
controlling, by the processor circuit and based on the diagnosed failure state of the battery, usage of the battery.

12. The method of claim 11, wherein the updating, by the processor circuit, of the multiclass algorithm comprises:
updating, by the processor circuit and based on a change rate of the first key data, a criterion, of the multiclass algorithm, for determining the failure of the battery.

13. The method of claim 12, wherein the identifying the first key data comprises:
identifying the first key data as comprising data associated with at least one of:
internal resistance of the battery, or
a state-of-health (SOH) of the battery, and
wherein the updating the multiclass algorithm comprises:
updating, by the processor circuit based on a change rate of the first key data, the criterion for determining the failure of the battery, wherein the change rate of the first key data comprises at least one of a maximum value of a change rate of the internal resistance, or a maximum value of a change rate of the SOH.

14. The method of claim 11, wherein the updating the multiclass algorithm comprises:
updating, by the processor circuit and based on a comparison between a change rate of the first key data and a predetermined change rate, at least one criterion selected from:
a criterion for determining that the battery is faulty,
a criterion for determining that the battery is at risk of failure, or
a criterion for determining that the battery is normal,
wherein the at least one criterion is of the multiclass algorithm.

15. The method of claim 11, further comprising:
identifying, by the processor circuit and from among the at least one key data, second key data for use in diagnosing the failure of the battery via the multiclass algorithm,
wherein the diagnosing the failure state of the battery comprises:
diagnosing, by the processor circuit and based on at least one of the second key data or the multiclass algorithm, the failure state of the battery.

16. The method of claim 15, wherein the identifying the second key data comprises:
identifying, by the processor circuit, the second key data as comprising data associated with at least one of:
a change in voltage of the battery,
a pseudo-diffusivity associated with the battery,
a signal parameter associated with the battery, or
an electrochemical parameter associated with the battery.

17. The method of claim 11, wherein the diagnosing the failure state of the battery comprises:
applying, by the processor circuit, the first key data to a neural network model that updates an equation based on newly input data to determine, by symbolic regression, a symbolic equation; and
updating, based on the symbolic equation, the multiclass algorithm.

18. The method of claim 17, wherein the diagnosing the failure state of the battery comprises:
diagnosing, by the processor circuit, the failure state of the battery based on at least one of:
the key data,
the symbolic equation, or
the multiclass algorithm.

19. The method of claim 17, wherein the neural network model comprises at least one of: a machine learning model or a deep learning model.

20. The method of claim 11, further comprising:
transmitting, by the processor circuit, the diagnosed failure state of the battery to at least one of:
the vehicle comprising the battery,
a device controlling the battery,
a display displaying the diagnosed failure state, or
a user terminal,
wherein the failure state indicates one or more of:
failure of the battery;
a risk level of failure of the battery; or
normal operation of the battery.
